(19) United States
(12) Patent Application Publication
(10) Pub. No.: US 2014/0125343 A1
(43) Pub. Date: May 8, 2014

(54) INSTRUMENT FOR MEASURING LED LIGHT SOURCE

(71) Applicant: Foxconn Technology Co., Ltd., New Taipei (TW)

(72) Inventor: TAY-JIAN LIU, New Taipei (TW)

(21) Appl. No.: 13/910,124

(22) Filed: Jun. 5, 2013

(30) Foreign Application Priority Data
Nov. 2, 2012 (CN) 2012104322965

(51) Int. Cl. G01R 31/26

(52) U.S. Cl. CPC G01R 31/2635
USPC 324/414

(57) ABSTRACT

A LED light source measuring instrument includes a shell portion and a test portion. The shell portion supports the test portion. The test portion includes an electrode seat, the electrode seat includes a first surface and a second surface opposite to the first surface. The first surface of the electrode seat provides two electrodes which electrically connect to the electrode plates of the LED light source for supplying power to the LED light source. The second surface of the electrode seat has a cooling device attached thereto for taking heat generated by the LED light source. A hole passing through the first surface and the second surface of the electrode seat is subjected to a vacuum, for automatically securing the electrode plates of the LED light source to the electrodes on the first surface of the electrode seat.

### BACKGROUND

1. Technical Field

The present disclosure relates to a light emitting diode (LED) light source measuring instrument, and particularly relates to a LED positioned and held in place through a vacuum, for testing purposes.

2. Description of Related Art

A photometrical and electrical measuring system of LED light source requires the insertion of a measuring instrument which carries a well-positioned LED light source into an integrating sphere; through connecting a peripheral spectrum analyzer, an electrical parameter measurement instrument and a LED power controller, measure the chromaticity coordinates, the color temperature, the color rendering index, the color tolerance adjustment, the wavelength, the color purity, the luminous flux, the voltage, the current and the power, and other properties of the LED light source. The typical LED light source used for the lighting fixture is a surface mounted technology (SMT) type LED, which is suitable for mass production. But there are many differences among the SMT LED light sources regarding size, shape, structure and types.

The electrode plates of the LED light source 203 for connecting with the power source as shown in FIG. 1 include a base positive electrode plate 2032 and a base negative electrode plate 2033 connecting with an underside of the LED light source 203 which is opposite to the light emitting surface 2031 of the LED light source 203; a longitudinal positive electrode plate 2132 and a longitudinal negative electrode plate 2133 are extending toward the longitudinal direction; a lateral positive electrode plate 2232 and a lateral negative electrode plate 2233 continue extending toward the lateral direction and parallel with the base positive and negative electrode plates 2032, 2033. In other prior art they do not have the structure with the lateral positive electrode plate 2232 and the lateral negative electrode plate 2233. Due to the miniaturization trend and cost considerations, manufacturers only provide the SMT LED light source with the base positive and negative electrode plates 2032, 2033. Also, since the test environment lacks temperature control, the measured LED light source 203 always stay in the transient state of temperature rise. Thus the long-term stability of the steady state test conditions cannot be clearly defined, resulting in the test data lack of reproducibility. Especially for the power type LED with power of more than 0.5 watts which is commonly used in lighting industry. Due to a lack of the thermal design or improper design of the prior art measuring instrument, the LED light source 203 may far exceed the allowable temperature limit because of the rapid temperature rises, and damage the LED light source 203, rendering the measurement result totally meaningless.

In prior art, the measuring instrument of LED light source can be divided into two types, a pressed-type measuring instrument 1a shown in FIG. 2, and a pushed-type measuring instrument 1b shown in FIG. 3. The pressed-type measuring instrument 1a includes a shell portion 10a made of a metal material in a hollow cylinder shape, and a testing portion 20a located at the opening end of the shell portion 10a. The size of an upper stage section 101a is matched with the entrance of the integrating sphere. The testing portion 20a is installed into the integrating sphere, then positioned on a stepped surface 103 which is located between the upper stage section 101a and a rear section 102a. The testing portion 20a is made of a non-metallic carrier plate 201a which is fixedly arranged at the opening end of the shell portion 10a; a pressed seat 301 is fixed on the carrier plate 201a, wherein the pressed seat 301 is made of metallic materials. A metal position-adjustable bolt 302 is arranged on the pressed seat 301 along the radial direction. The nuts of the adjustable bolts 302 are connected with different polarities, become as a positive electrode 205a and a negative electrode 210a which supply the power to the LED light source 203. A supporting seat 303 is arranged inside the shell portion 10a and supports an axial spring member 304. An inverted U-shaped top plate 305 is on the top of the axial spring member 304, and moves upward by spring expansion. The top plate 305 is limited and can only slide axially through the size matching between the cylindrical wall of the top plate 305 and the wall surface of the central through hole of the carrier plate 201a. The central region of the end surface of the top plate 305 is the electrical insulation under test zone.

When the pressed-type measuring instrument 1a is not placed with the LED light source 203, the end surface of the top plate 305 directly contacts the positive and negative electrodes 205a, 210a of the adjustable bolts 302. When operating, the LED light source 203 is placed on the pressed-type measuring instrument 1a first; then the top plate 305 is pressed to adjust the position of the positive and negative electrodes 205a, 210a according to the size of the lateral positive and negative electrode plates 2232, 2233 of the LED light source 203, according to FIG. 1. The LED light source 203 is thus placed in the test zone of the top plate 305, and makes contact with the positive and negative electrodes 205a, 210a of the measuring instrument 1a by compressing the lateral positive and negative electrode plates 2232, 2233 of the LED light source 203, respectively. To achieve the testing state, the LED light source 203 is sandwiched between the top plate 305 and the pair of electrodes 205a, 210a of the adjustable bolt 302.

Since the pressed seat 301, the adjustable bolts 302 and the pair of electrodes 205a, 210a of the pressed-type measuring instrument 1a are necessarily arranged above the light emitting surface 2031 of the LED light source 203, serious light blocking will further interfere with the measured luminous flux value, and the application of the pressed-type measuring instrument 1a is limited only in a few of the lateral positive and negative electrode plates 2232,2233 of the LED light source 203. Using this measuring instrument 1a to measure different sizes and shapes of LED light source 203 has its limitations and operating inconveniences, particularly in the non-temperature controlled test environment, resulting in the lack of reproducibility of measurement data, even causing damage to the LED light source 203. Thus, the pressed-type measuring instrument 1a has serious limitations and shortcomings in both measuring quality and breadth of application.

FIG. 3 shows the pushed-type measuring instrument 1b. The main differences between the pressed-type and pushed-type measuring instruments 1a, 1b are that there is a flat shallow trench 412 through a center of a carrier plate 201b; the bottom of a negative electrode assembly 402 is fixed inside the trench 412; a positive electrode assembly 401 can slide freely along the trench 412; the positive and negative electrode assemblies 401, 402 are made of electrically insulating material. Two metal thimbles 205b, 210b extend respectively from the positive and negative electrode assemblies 401, 402 toward the LED light source 203. The two metal thimbles 205b, 210b are electrically connected with a power source thereby making the two metal thimbles 205b, 210b form a pair of positive and negative electrodes 205b, 210b for the pushed-type measuring instrument 1b.

The movement of the positive electrode assembly 401 is along a long trench 409 which opens through the carrier plate 201b to communicate with the trench 412. A spring member 404 is arranged inside a shell portion 10b by a screw passing through the long trench 409 to connect with the positive electrode assembly 401, so that the positive electrode assembly 401 is fixed to a slider 405. The slider 405 is in the middle of the spring member 404. One side of the slider 405 along the radial direction has a guide rod 406, the end of the guide rod 406 is extending towards but not beyond the outer wall surface of an upper stage section 101b. The other side of the slider 405 along the radial direction locates a fixing screw 407 which extends through the upper stage section 101b, and allows a spring 408 to extend into a blind hole of the slider 405. The blind hole, the guide rod 406 and the fixing screw 407 are coaxially aligned. When operating the pushed-type measuring instrument 1b, the guide rod 406 is gently pushed a certain distance to enable the slider 405 to slide along the trench 412, making the positive electrode assembly 401 move the same distance away from the fixed negative electrode assembly 402, to place the LED light source 203 properly between the electrode assemblies 401, 402. When the pushing on the guide rod 406 is released, the positive electrode assembly 401 moves close to the LED light source 203 to electrically engage the longitudinal positive electrode plate 2132.

According to the size of the LED light source 203, the positive and negative electrodes 205b, 210b of the positive and negative electrodes assembly 401, 402 of the pushed-type measuring instrument 1b are in contact with and supply power to the longitudinal positive and negative electrode plates 2132, 2133 of the LED light source 203. However, the heights of the positive and negative electrode assemblies 401, 402 of the pushed-type measuring instrument 1b and the longitudinal positive and negative electrode plates 2132, 2133 of the LED light source 203 are fixed and may not match each other. Additionally, the amount of the displacement of the slider 405 is limited via pushing the guide rod 406, the size of the LED light source 203 is varied in the market, and the LED light source 203 may not have the longitudinal positive and negative electrode plates 2132, 2133. Therefore, using the same pushed-type measuring instrument 1b to measure different sizes and shapes of the LED light source 203 has its limitations. The pushed-type measuring instrument 1b is only suitable for the type of the LED light source 203 with the longitudinal electrode plates 2131, 2133, particularly in the non-temperature controlled test environment where the steady-state test conditions cannot be clearly defined. Thus, the pushed-type measuring instrument 1b has its limitations and shortcomings in measuring quality and the breadth of application.

In order to reduce the impact of the temperature rise during the measurement process, the current market has a pulsed DC power supply for measuring the LED light source 203, and claims that the measuring instrument can retrieve the transient data of the photometrical and electrical parameters within a fraction of a second after lighting the LED light source 203. However, any heat sources including the LED light source 203 in the initial temperature rise transient process must be the fastest and most dramatic particularly in the power type LED. After a long-term experimental confirmation, under the test conditions which do not result in the damage of the LED light source 203, there is evidence that the initial luminous flux of the data as to transience are more than double that of the long-term stability of the steady state flux data. The transient flux data show very big differences at different time instants for initial lighting and lose reproducibility when applied in analyses on different occasions to the same LED light source 203, resulting in only the LED manufacturer strongly advocating and providing such transient data to the end user. However, for the LED lighting industry, the useful reference value should pay attention to the long-term steady state lighting performance. The initial transient data provided by a vendor is completely meaningless. The standardization of the LED light source 203 measurement method (CIE 127:2007, MEASUREMENT OF LEDS) indicates that the above initial transient data must be clearly correlated to the steady state data, but the correlation will be different with different manufactures of LEDs. For the majority of the lighting applications, end users are completely unable to understand the meaning of the norms of transient data; therefore, the transient data of the LED light source 203 lacks predictability and practicability. Accordingly, measurement of the LED light source 203 still needs to be in line with the practical application and has long-term reproducibility, and reliable data.

Therefore, it is necessary to provide a way for non-destructive measurement of LED light source under a well-defined constant temperature steady state conditions, and use an LED light source measuring instrument with no light blocking, easy operation, high precision and versatility.

### BRIEF DESCRIPTION OF THE DRAWINGS

Many aspects of the present LED light source measuring instrument can be better understood with reference to the following drawings. The components in the drawings are not necessarily drawn to scale, the emphasis instead being placed upon clearly illustrating the principles of the present LED light source measuring instrument. In the drawing, all the views are schematic.

FIG. 1 is a perspective view of a typical LED light source.

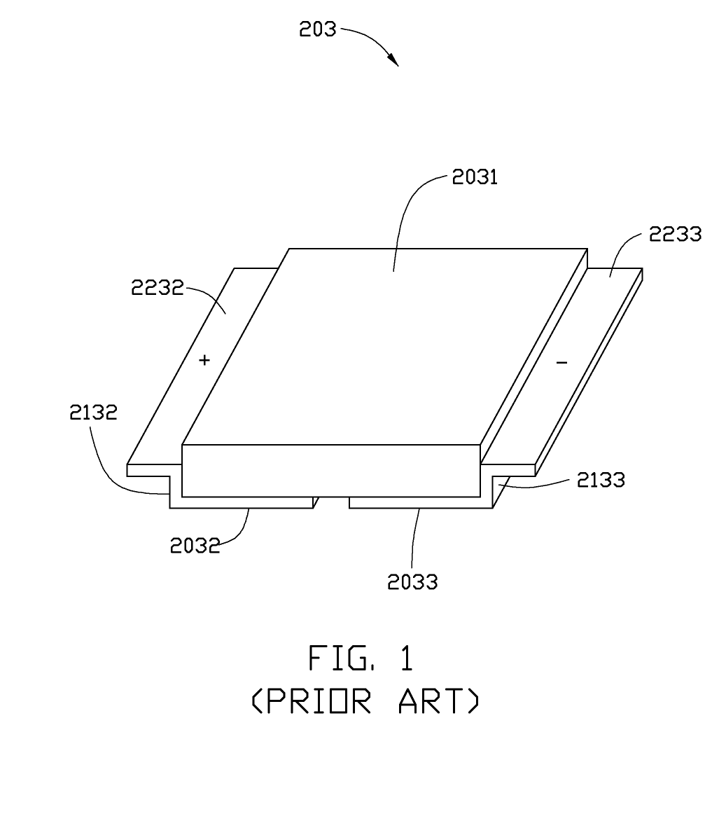

FIG. 2 is a schematic cross sectional view of a prior art measuring instrument for measuring the characteristics of the LED light source of FIG. 1.

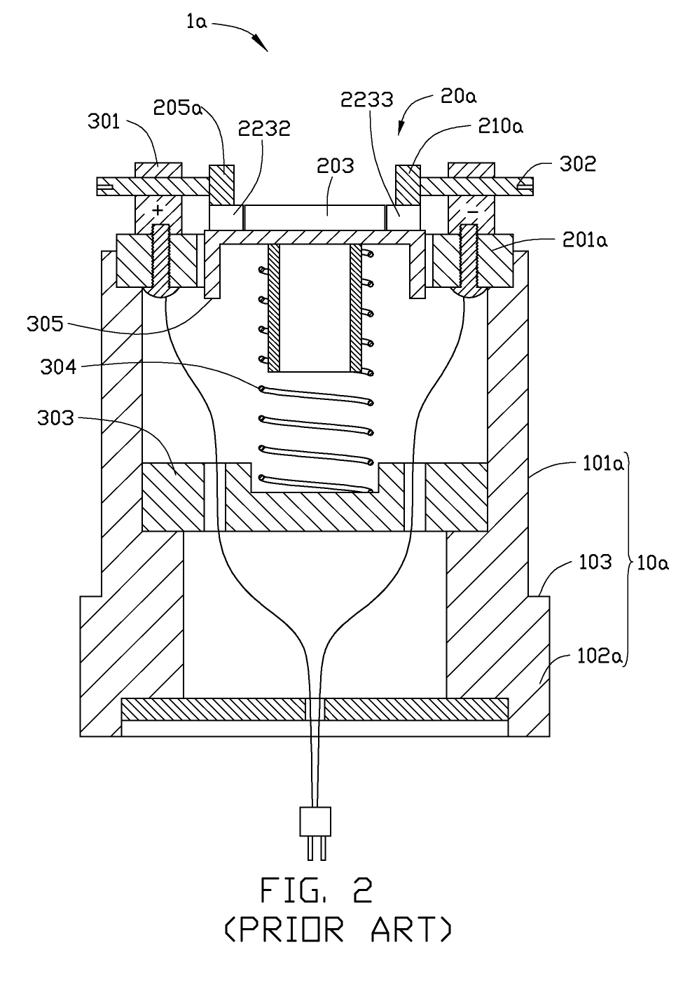

FIG. 3 is a schematic cross sectional view of another prior art measuring instrument.

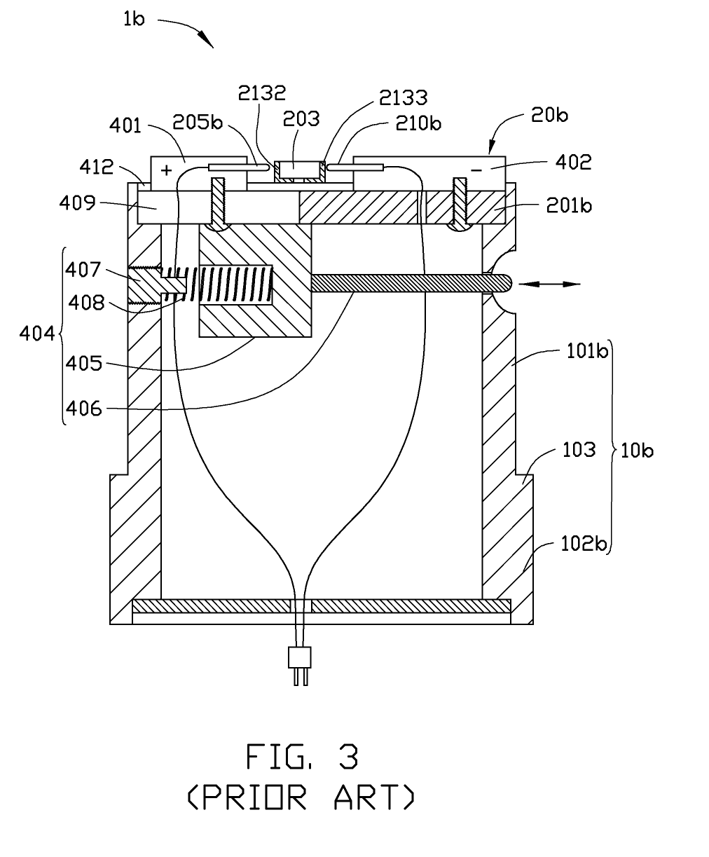

FIG. 4 is a schematic cross sectional view of a LED measuring instrument in accordance with an embodiment of the present disclosure.

FIG. 5 is a top view, partly in cross section, of a test portion of the LED measuring instrument of FIG. 4, wherein an electrode seat of the test portion is removed for clarity.

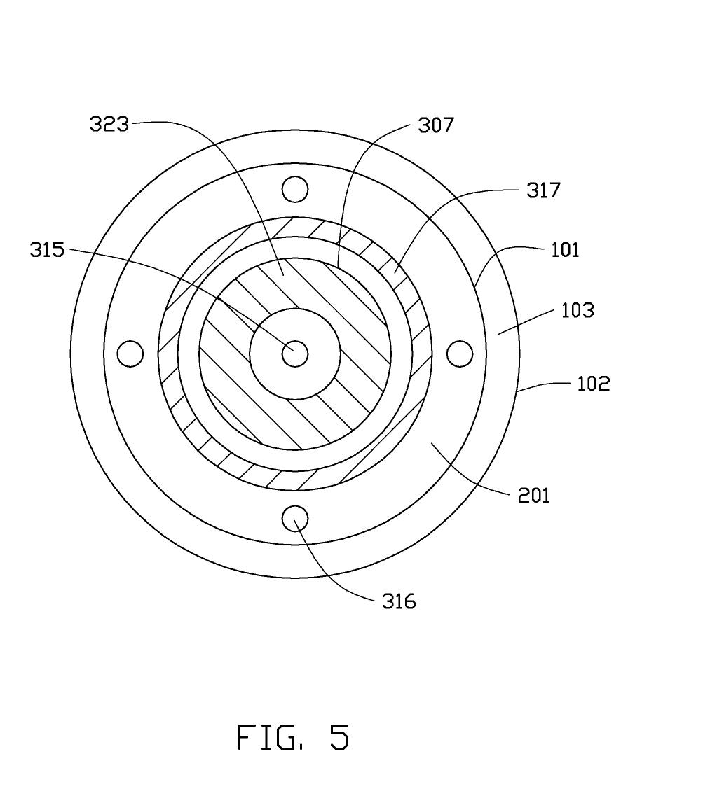

FIG. 6 is a top view of the electrode seat of the test portion of the LED measuring instrument of FIG. 4.

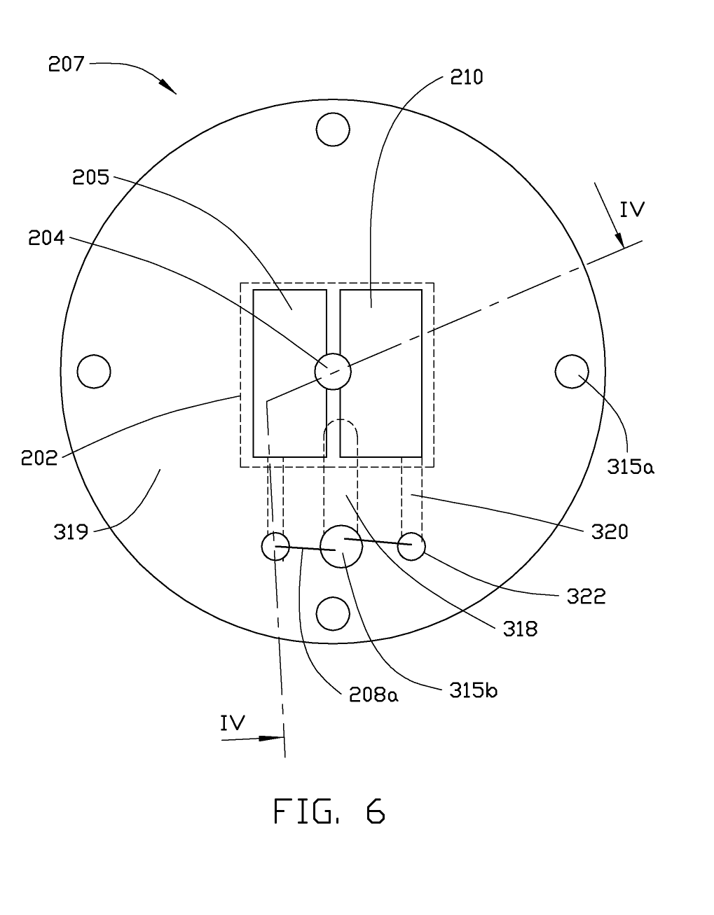

FIG. 7 is a schematic cross sectional view of the electrode seat along IV-IV line of FIG. 6.

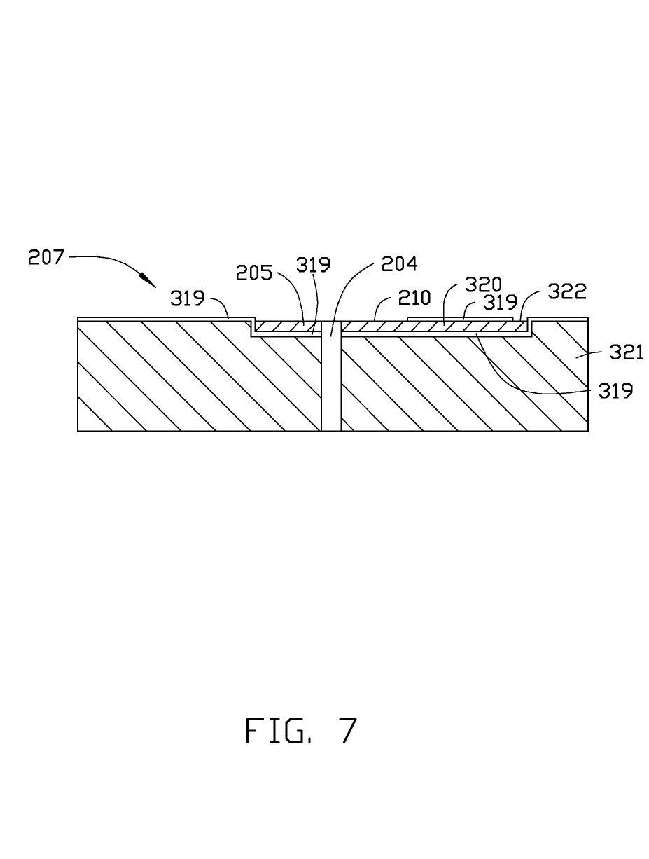

### DETAILED DESCRIPTION

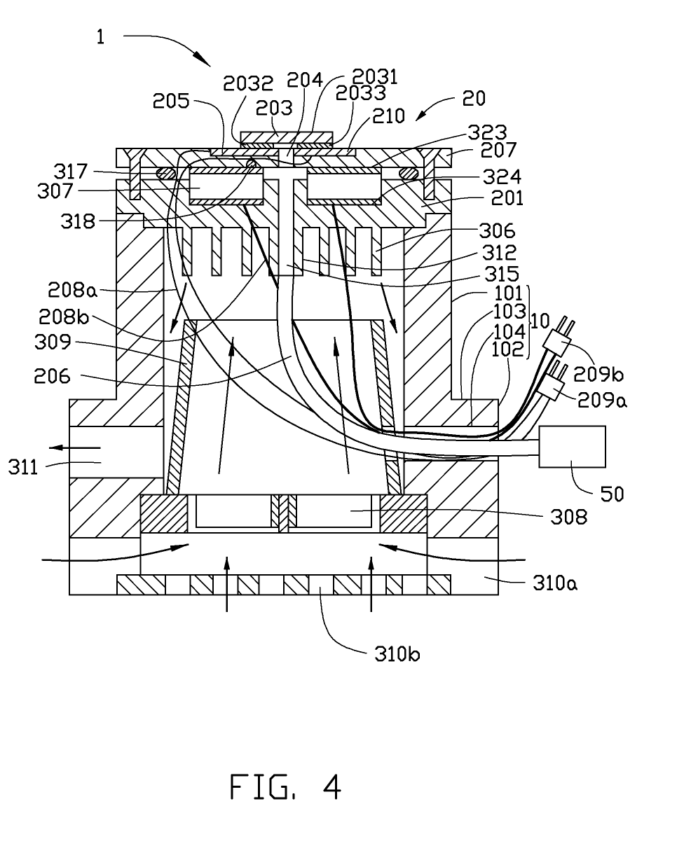

FIG. 4 is a schematic cross sectional view of a LED measuring instrument 1 in accordance with an embodiment of the present disclosure. The measuring instrument 1 includes a shell portion 10 and a test portion 20. The shell portion 10 is a hollow cylinder and has at least one side opening for receiving the test portion 20. An outer peripheral wall surface of the cylinder axially extends from the opening into a thinner upper stage section 101, and forms a right angle stepped surface 103 between the thinner upper stage section 101 and a thicker rear section 102. The outer peripheral wall size and shape of the upper stage section 101 match and correspond to an inner surrounding wall surface of tubular entrance of an integrating sphere (not shown). The stepped surface 103 abuts against the tubular end of the entrance, to achieve the test portion 20 being inserted and positioned into the integrating sphere, so that a LED light source 203 of the test portion 20 is in under test status.

The test portion 20 includes a carrier plate 201 embedded in an opening end of the shell portion 10, and a heat sink fin 306 downwardly extending from a bottom side of the carrier plate 201 opposite the LED light source 203 and toward an inside of the shell portion 10. The heat sink fin 306 is around the periphery of a central cylinder 312, and formed as a spiral plate; the heat sink fin 306 may also use other types, such as a plurality of coaxial plates extending downwardly from the bottom side of the carrier plate 201, pin fins, louver fins, etc. The heat sink fin 306 enables the carrier plate 201 to increase heat dissipation area and enhances the heat conducting path, whereby heat generated by the LED light source 203 on the outer end surface of carrier plate 201 can be dissipated quickly. A space is defined between the end edge of the heat sink fin 306 and the inner wall of the shell portion 10 for smoothing the path of the cooling airflow. The center of the carrier plate 201 defines a through hole 315, which passes through the carrier plate 201 and the central cylinder 312. A flexible tube 206 is used to connect with the central cylinder 312 and extends through a wall hole 104 passed through the rear section 102 of the shell portion 10, and connects with a vacuum pump 50 outside the shell portion 10.

Inside the carrier plate 201, an annular shape Peltier cooling chip 307 surrounds the through hole 315. A cooling surface 323 of the cooling chip 307 is slightly higher than a top surface of the carrier plate 201. An electrode seat 207 is attached to the cooling surface 323. An air hole 204 connects with the through hole 315 set at the center of the electrode seat 207, and at least one pair of the electrodes 205, 210 are positioned at neighboring opposite sides of the air hole 204, backward to the cooling surface 323, for connecting with externally controlled power supply to conduct positive and negative voltages. A sealing coil 317 surrounds the cooling chip 307 and is set on the carrier plate 201, and four screw holes 316 are set in the carrier plate 201 and located at the peripheral of the sealing coil 317. Via screws which separately pass through through holes 315a located in the periphery of the electrode seat 207, for screw locking into the corresponding screw holes 316, the electrode seat 207 and the carrier plate 201 are secured together, whereby the cooling chip 307 is pressed downwards by the electrode seat 207 toward the carrier plate 201. A good thermal contact between a heating surface 324 of the cooling chip 307 and the carrier plate 201 is thus made, enhancing the effectiveness of the thermal conductivity and the heat dissipation abilities of the cooling chip 307. A good thermal contact is also created between the electrode seat 207 and the cooling surface 323 of the cooling chip 307, further enhancing the effectiveness of cooling temperature control of the cooling chip 307 for the LED light source 203. The peripheries of a space between the electrode seat 207 and the carrier plate 201 are sealed via the screws and the sealing coil 307, enabling base positive and negative electrode plates, 2032, 2033 of the LED light source 203 and the positive and negative electrodes 205, 210 to be firmly in contact via a vacuum force provided by the vacuum pump 50 through the air hole 204. In the bottom of the shell portion 10 a fan 308 is provided, wherein the fan 308 blows the cold air from outside onto the heat sink fin 306; the endothermic airflow released from the LED light source 203 and the heating surface 324 of the cooling chip 307 is discharged out of the integrating sphere and is cooled by the cold air from the fan 308; the central bottom side of the LED light source 203 abuts the air hole 204, through the vacuum force provided by the vacuum pump 50, making electrical connections to the base positive and negative electrode plates 2032, 2033 attached to the surface of the electrode seat 207, and power is then supplied to the LED light source 203.

The electrode seat 207 is a copper-coated aluminum substrate with good thermal and electrical conductivity; a four-layer assembly of the electrode seat 207 is formed by a unique process; the structure of the electrode seat 207 from top to bottom is as follows: an electrical insulation layer 319 which is formed by a special polymer with good thermal conductivity and electrical insulation, a circuit layer 320 which is formed by a copper foil material with good thermal and electrical conductivity, the thermal insulation layer 319, and a metal base layer 321 which is formed by an aluminum material with good thermal conductivity. Operating principle of the electrode seat 207 is to make the base positive and negative electrode plates 2032, 2033 of the LED light source 203, via the vacuum force attached to the circuit layer 320, which corresponds to the positive and negative electrodes 205, 210, and then supply power to the LED light source 203. Heat generated by the LED light source 203, via the base positive and negative electrode plates 2032, 2033, is conducted through the low thermal resistance, electrical insulation layer 319 and by conduction to the metal base layer 321, being finally absorbed by the cooling surface 323 which is tightly attached to the metal base layer 321, enabling the LED light source 203 to be maintained in a low temperature operating environment. The pair of the electrodes 205, 210 is made by copper foil in a rectangular shape and arranged at intervals at both sides of the air hole 204 on the electrode seat 207; the design is convenient for ensuring contact with the base positive and negative electrode plates 2032, 2033 of the LED light source 203. The pair of the electrodes 205, 210 extends to a copper foil soldering ends 322 outside an under test zone 202, and is coated with the electrical insulation layer 319 between the metal base layer 321 and the electrodes 205, 210, to prevent electrical conduction by the metal base layer 321. The positive and negative electrodes 205, 210 are connected to an external control power supply (not shown) via two electric wires 208a using a plug 209a; the two electric wires 208a extend from a through hole 315b and are soldered in the soldering ends 322.

To impose a stronger vacuum force on the base positive, negative electrode plates 2032, 2033 of the LED light source 203, and between the carrier plate 201 and the electrode seat 207, the rest of the space must be airtight, ensuring that the air hole 204 is the only place to create the vacuum force via the vacuum pump 50; in order to ensure better thermal conductivity and electrical safety between the pair of positive and negative electrode plates 2032, 2033 and the pair of electrodes 205, 210, the rest surface of the electrode seat 207 is laid with laying the electrical insulation layer 319 expect the copper coil of the electrodes 205, 210 and the soldering ends 322. Preferred sizes of the copper foil electrodes 205, 210 are adjustable for attaching various sizes of LED. In actual use, the thickness range of the electrical insulation layer 319 of the electrode plate 207 is 5 μm˜20 μm, the thickness range of the circuit layer 320 is 35 μm˜350 μm, and the thickness range of the metal base layer 321 is 0.8 mm˜2 mm.

The cooling chip 307 (also known as thermoelectric cooler, semiconductor refrigeration, or heat pump) of the measuring instrument 1 consists of a plurality of cooling dies made from different types of materials such as bismuth telluride packaged into two electrically insulating ceramic plates on both sides. When DC current flows through the cooling chip 307, by the Peltier effect, a heat flux is created between the junction of adjacent two dies and heat is brought from one side to the other, so that one side gets cooler while the other gets hotter. The hot side is attached to the carrier plate 201 having the heat sink fin 306 so that it remains at ambient temperature, while the cool side goes below room temperature. The present disclosure uses the annular cooling chip 307, the bottom side of the annular plate of the cooling chip 307 functions as a heating (heat dissipating) surface 324 tightly attached to the grooved top surface of the carrier plate 201, and the upper side of the annular plate functions as a cooling (heat absorbing) surface 323 tightly attached to the surface of the metal base layer 321 of the electrode seat 207. The cooling chip 307 may also use other shapes. Two electric wires 208b are electrically connected with the cooling chip 307 using a plug 209b connected to an external control power supply (not shown), to supply power to the cooling chip 307. The electric wires 208b pass through the carrier plate 201, the heat sink fin 306, and the wall hole 104, to the outside of the rear section 102 of the shell portion 10.

A thermal sensor 318 (e.g., thermistor or thermocouple) is attached on the cooling surface 323 of the cooling chip 307; by means of connecting the thermal sensor 318 to a temperature control circuit (not shown) and setting the temperature of the cooling surface 323 via a temperature monitor (not shown), the cooling surface 323 is thus maintained at low temperature (e.g., 10° C. or 20° C.) during measurement. Heat released from LED light source 203 into the under test zone 202 is absorbed by the cooling surface 323. So that, the measurement of an LED light source 203 can always be at a controlled low temperature, thereby the LED light source 203 is prevented from being damaged by excessive temperatures. One of the preferred embodiments for installing the thermal sensor 318 is as follows: setting a groove on a surface of the metal base layer 321 close to the cooling surface 323 at the bottom of the electrode seat 207 for receiving the thermal sensor 318 and its conductive wires, the conductive wires extending from the through hole 315b, the groove and the through hole 315b then being filled with a thermal plastic and cured. In order to achieve above mentioned low temperature measurement to prevent the heating surface 324 of the cooling chip 307 from being unable to dissipate heat from the cooling surface 323 (whereby the temperature would rise and the thermal energy would backflow to the cooling surface 323), the present disclosure discloses the use of the carrier plate 201 to conduct the heat released from heating surface 324 of the cooling chip 307 to the heat sink fin 306. In addition, in the rear section 102 of the shell portion 10 close to the inner wall surface of the bottom a fan 308 is provided, wherein the fan 308 blows the cold air from outside into the heat sink fin 306; the spiral direction of the spiral heat sink fin 306 is consistent with the rotational direction of the fan 308, enabling the cooling airflow easily lead to the heat sink fin 306 to remove heat therefrom.

Before the measuring instrument 1 is inserted into the integrating sphere, the fan 308 draws in the cooling airflow via a plurality of lateral air inlets 310a, wherein the lateral air inlets 310a partially surround the fan 308 and are located around the lower side of the rear section 102. When the measuring instrument 1 is inserted into the integrating sphere, the fan 308 draws in the cooling airflow via both a plurality of axial air inlets 310b located at the bottom side of the rear section 102, and also the lateral air inlets 310a. At the air outlet of the fan 308 there is a tapered wind guider 309 toward the heat sink fin 306; the outlet of the wind guider 309 covers the axial free end of the heat sink fin 306, in order to accelerate and guide the converged cooling airflow onto the heat sink fin 306 and the carrier plate 201. An endothermic airflow of the neighboring heat sink fin 306 via the spacing between the side edge of the heat sink fin 306 and the inner wall of the upper stage section 101 is guided into an annular channel formed between the inner wall surface of the upper stage section 101 and the outer wall surface of the wind guider 309. Then, via a plurality of air outlets 311 spaced in the wall surface of the rear section 102, the endothermic airflow released from the LED light source 203 and the heating surface 324 of the cooling chip 307 is discharged out of the integrating sphere and the measuring instrument 1.

When operating the measuring instrument 1, first step is to turn on the vacuum pump 50, and then place the LED light source 203 on the under test zone 202, make the central bottom side of the LED light source 203 abut the air hole 204, and make the base positive and negative electrode plates 2032, 2033 abut the at least one pair of electrodes 205, 210. The light emitting surface 2031 of the LED light source 203 is at the top side thereof, which is opposite to the bottom side of the base positive and negative electrode plates 2032, 2033. Through a vacuum force provided by the vacuum pump 50, the LED light source 203 is attached and firmly fixed on the under test zone 202 via the vacuum force in the air hole 204. Simultaneously, at least one pair of the electrodes 205, 210 with different polarities makes forceful contact with the base positive and negative electrode plates 2032, 2033 respectively of the LED light source 203. After the predetermined temperature of the cooling surface 323 of the annular cooling chip 307 is set and the fan 308 is turned on, external electrical power is supplied to the cooling chip 307; then the measuring instrument 1 is inserted into the entrance of the integrating sphere. The external control power is adjusted and stabilized until the operating current and voltage of the LED light source 203 meet the specification; then, turn on the power for lighting the LED light source 203 inside the integrating sphere. Confirm the temperature of the cooling surface 323 reaches stability state by the temperature display, startup the automatic measurement system of the photometrical and electrical properties of the LED light source 203. When measurements are completed, turn off the external power to extinguish the LED light source 203, then remove the measuring instrument 1 from the integrating sphere, and remove the LED light source 203, continue to place another LED light source 203 on the under test zone 202 for measurement.

Compared to the conventional LED light source measuring instruments 1a, 1b, since the present embodiment utilizes a vacuum pump 50 to provide the vacuum force at the bottom of the LED light source 203, the present disclosure achieves a close and easily positioned attachment of the LED light source 203 on the front most surface of the measuring instrument 1, and simultaneous electrically connected to the base positive and negative electrode plates 2032, 2033, directly attaching the unique electrode seat 207 on the cooling surface 323, enabling protection of the LED light source by a controlled low temperature of cooling surface 323, completely avoiding the light blocking shortcomings of the conventional measuring instruments 1a, 1b, and completely avoiding inadvertent and variable temperature rises in the LED light source 203, which may cause measurement uncertainty and risk of destruction; moreover, the measuring instrument 1 of the present disclosure has a simpler structure than conventional measuring instruments 1a, 1b. In present disclosure, power can be supplied to any SMT type LED light source with base positive and negative electrode plates 2032, 2033; the present disclosure can be used to measure different sizes, shapes, structures and types of the LED light source without any restriction, ensuring excellent measurement quality and extreme versatility of the LED light source measuring instrument 1.

In the above embodiment the technical features and the significant effects of the present disclosure are clearly described, including: the vacuum force is utilized to easily attach and fix the SMT type LED on the under test zone; and the LED light source is powered by contact between the base positive and negative electrode plates of the LED light source and the positive and negative electrodes of the measuring instrument. The LED light source is maintained at the front most surface of the measuring instrument, to overcome the light blocking shortcomings of the conventional measuring instrument, and to achieve high precision in measuring the photometrical and electrical performance of LED light sources.

The present disclosure provides a LED measuring instrument which can maintain the LED light source under protection and different ambient temperatures to carry out steady state photometrical and electrical measurements. Aside from the electrode seat formed by the four-layer assembly configuring with electrical insulation layers coating on circuit layer, metal base layer, and directly attaching to the cooling surface of the cooling chip, the present disclosure provides high and efficient heat dissipation and smoothes the path of the cooling airflow, whereby the heat released from the LED light source and from the heating surface of the cooling chip can be exhausted out of the LED measuring instrument and the integrating sphere quickly. The quick release of the heat from the LED light source effectively eliminates measurement errors and risk of damage to the LED light source caused by rapid temperature rise of the LED light source.

The present disclosure provides a measuring instrument which can be applied to any size or type of SMT type LED, supply power to any SMT type LED light source there must be with base positive and negative electrode plates, regardless with or without either the longitudinal or lateral electrode plates; thus all the different types of SMT type LEDs can be measured by the LED measuring instrument of the present disclosure.

The present disclosure provides an SMT-type LED measuring instrument with a simple structure, easy operation, without any positioning fixtures with complex structure, compared to the conventional measuring instrument. The installation and removal of the LED light source is simplified, the manufacture of the measuring instrument is streamlined, the cost is reduced, the use of the measuring instrument is simplified, and measurement quality and long term reliability are ensured.

Although the present disclosure has been specifically described on the basis of this exemplary embodiment, the disclosure is not to be construed as being limited thereto. Various changes or modifications may be made to the embodiment without departing from the scope and spirit of the disclosure.

What is claimed is:

1. A LED (light emitting diode) light source measuring instrument for measuring characteristics of a LED light source, comprising a shell portion and a test portion, the shell portion supporting the test portion, the test portion comprising an electrode seat, the electrode seat comprising:
a first surface having two electrodes electrically connecting to electrode plates of the LED light source for supplying power to the LED light source;
a second surface opposite to the first surface having a cooling device attached thereon for taking heat generated by the LED light source;
at least one air hole passing through the first surface and the second surface of the electrode seat; and
a vacuum suction device being in communication with the at least one air hole for providing a vacuum force to secure the LED light source to the first surface of the electrode seat and cause the electrode plates of the LED light source to electrical connect with the electrodes on the first surface of the electrode seat.

2. The LED light source measuring instrument as claimed in claim 1, wherein the cooling device comprises a cooling chip attaching to the second surface of the electrode seat.

3. The LED light source measuring instrument as claimed in claim 2, wherein the cooling device comprises a carrier plate arranging on the top of the shell portion, the cooling chip setting between the carrier plate and the electrode seat.

4. The LED light source measuring instrument as claimed in claim 3, wherein the carrier plate setting a through hole corresponding to the air hole of the electrode seat, the vacuum suction device secures the LED light source via the through hole and the air hole.

5. The LED light source measuring instrument as claimed in claim 3, wherein between the carrier plate and the electrode seat setting a sealing coil surrounds the cooling chip.

6. The LED light source measuring instrument as claimed in claim 3, wherein a heat sink fin axially extending from a side of the carrier plate opposite the LED light source and toward the inside of the shell portion.

7. The LED light source measuring instrument as claimed in claim 6, wherein inside the shell portion comprises a fan and a wind guider, wherein the fan blows a cold air from outside onto the heat sink fin via the wind guider, the cold air carries out a heat exchange with the carrier plate, then through a space between the wind guider and an inside of the shell portion to be discharged out of the shell portion.

8. The LED light source measuring instrument as claimed in claim 7, wherein the shell portion comprises an upper stage section and a rear section, the carrier plate setting on the upper stage section of the shell portion, at least one air inlet setting on an end of the rear section of the shell portion, at least one air outlet setting on a lateral side of the rear section of the shell portion.

9. The LED light source measuring instrument as claimed in claim 1, wherein the electrode seat comprises a metal base layer, a first electrical insulation layer setting on the metal base layer, and a circuit layer setting on the electrical insulation layer, the two electrodes of the electrode seat being formed by the circuit layer.

10. The LED light source measuring instrument as claimed in claim 9, wherein the electrode seat comprises a second electrical insulation layer covering the circuit layer, an area of the circuit layer not covered by the second electrical insulation layer forming the two electrodes and soldering ends of the electrode seat, electric wires soldered in the soldering ends and connecting to an external power supply to supply power to the LED light source.

11. The LED light source measuring instrument as claimed in claim 9, wherein a thermal sensor is adjacent to a cooling surface of the cooling chip to measure a temperature of the cooling surface.

12. The LED light source measuring instrument as claimed in claim 11, wherein the thermal sensor is received in a groove defined in the electrode seat.

13. The LED light source measuring instrument as claimed in claim 1, wherein the vacuum suction device is a vacuum pump.
